(19) United States
(12) Patent Application Publication
(10) Pub. No.: US 2026/0361231 A1
(43) Pub. Date: Nov. 12, 2026

(54) SYSTEMS AND METHODS FOR INTEGRATED COMMON MODE FILTER FOR ELECTRIC VEHICLE

(71) Applicant: BorgWarner Inc., Auburn Hills, MI (US)

(72) Inventors: Andreas MAYER, Clarkston, MI (US); Elanchetchenni ADIAMAN, Sterling Heights, MI (US)

(73) Assignee: BorgWarner Inc., Auburn Hills, MI (US)

(21) Appl. No.: 19/200,916

(22) Filed: May 7, 2025

(51) Int. Cl. H02M 7/00; H05K 7/14; H05K 7/20

(52) U.S. Cl. CPC H02M 7/003; H05K 7/1432; H05K 7/20927

(57) ABSTRACT

A system includes an inverter configured to convert DC power from a battery to AC power to drive a motor, wherein the inverter includes a printed circuit board, wherein the printed circuit board includes at least one high voltage layer including a conductive plate; and at least one cold plate electrically insulated from the at least one high voltage layer, wherein the at least one cold plate is electrically connected to ground.

### TECHNICAL FIELD

Various embodiments of the present disclosure relate generally to systems and methods for inverters, and, more particularly, to systems and methods for common mode filters for inverters for electric vehicles.

### BACKGROUND

Inverters, such as those used to drive a motor in an electric vehicle, for example, are responsible for converting High Voltage Direct Current (HVDC) into Alternating Current (AC) to drive the motor. In an inverter, noise and other signals can compromise operation of the inverter.

The present disclosure is directed to overcoming one or more of these above-referenced challenges.

### SUMMARY OF THE DISCLOSURE

In some aspects, the techniques described herein relate to a system including: an inverter configured to convert DC power from a battery to AC power to drive a motor, wherein the inverter includes: a printed circuit board, wherein the printed circuit board includes: at least one high voltage layer including a conductive plate; and at least one cold plate electrically insulated from the at least one high voltage layer, wherein the at least one cold plate is electrically connected to ground.

In some aspects, the techniques described herein relate to a system, wherein the inverter is double side cooled and the inverter is PCB based with embedded power devices or switches.

In some aspects, the techniques described herein relate to a system, wherein the at least one high voltage layer includes a first high voltage plate and a second high voltage plate, wherein the first high voltage plate is a positive high voltage plate, and wherein the second high voltage plate is a negative high voltage plate.

In some aspects, the techniques described herein relate to a system, further including at least one system layer, wherein a first face of the at least one system layer is directly adjacent to a face of at least one high voltage plate, and a second face of the at least one system layer is directly adjacent to a face of the at least one cold plate.

In some aspects, the techniques described herein relate to a system, wherein the at least one system layer includes a solder mask.

In some aspects, the techniques described herein relate to a system, wherein the at least one system layer includes a gap filler material.

In some aspects, the techniques described herein relate to a system, wherein a thickness of the at least one system layer is configured to determine a distance between the at least one high voltage plate and the at least one cold plate.

In some aspects, the techniques described herein relate to a system, wherein a thickness of the at least one system layer is configured to determine an effective dielectric constant between the at least one high voltage plate and the at least one cold plate.

In some aspects, the techniques described herein relate to a system, wherein the at least one high voltage plate, the at least one cold plate, and the at least one system layer are configured to produce a capacitance.

In some aspects, the techniques described herein relate to a system, wherein the at least one high voltage plate is a first conductor and the at least one cold plate is a second conductor, and wherein the at least one system layer has a thickness equal to a distance between the first conductor and the second conductor, wherein the distance between the first conductor and the second conductor is the distance in between the face of the at least one high voltage plate and the face of the at least one cold plate.

In some aspects, the techniques described herein relate to a system, wherein the at least one high voltage plate, the at least one cold plate, and the at least one system layer are configured as a common mode electromagnetic interference filter.

In some aspects, the techniques described herein relate to a system, wherein the at least one high voltage plate, the at least one cold plate, and the at least one system layer are configured as Y-capacitor.

In some aspects, the techniques described herein relate to a system, further including: one or more batteries, wherein the system is provided as a bidirectional battery charger configured to: receive an input AC power from a line voltage, convert the input AC power to an output DC power, and supply the output DC power to charge the one or more batteries in a grid-to-battery operation, and receive an input DC power from the one or more batteries, convert the input DC power to an output AC power, and supply the output AC power to a load of the line voltage in a battery-to-grid operation.

In some aspects, the techniques described herein relate to a system, further including: the battery; and the motor, wherein the system is provided as an electric vehicle.

In some aspects, the techniques described herein relate to a system including: a printed circuit board, wherein the printed circuit board includes: a first high voltage plate, a first cold plate electrically connected to a ground, a first system layer electrically insulating the first high voltage plate from the first cold plate, a second high voltage plate, a second cold plate electrically connected to the ground, and a second system layer electrically insulating the first high voltage plate from the second cold plate.

In some aspects, the techniques described herein relate to a system, wherein the first high voltage plate, the first cold plate, and the first system layer are configured to provide a first capacitance, and wherein the second high voltage plate, the second cold plate, and the second system layer are configured to provide a second capacitance.

In some aspects, the techniques described herein relate to a system, wherein the first system layer includes one or more first system layers, and the second system layer includes one or more second system layers.

In some aspects, the techniques described herein relate to a system, wherein the first high voltage plate, the first cold plate, and the first system layer, are provided as a Y-capacitor, and the second high voltage plate, the second cold plate, and the second system layer are provided as a second Y-capacitor.

In some aspects, the techniques described herein relate to a system including: a printed circuit board, wherein the printed circuit board includes: at least one high voltage plate; and at least one cold plate electrically insulated from the at least one high voltage plate, wherein the at least one cold plate is electrically connected to ground.

In some aspects, the techniques described herein relate to a system, further including at least one system layer, and wherein the at least one system layer, the at least one high voltage plate, and the at least one cold plate are provided as a Y-capacitor.

Additional objects and advantages of the disclosed embodiments will be set forth in part in the description that follows, and in part will be apparent from the description, or may be learned by practice of the disclosed embodiments. The objects and advantages of the disclosed embodiments will be realized and attained by means of the elements and combinations particularly pointed out in the appended claims.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 depicts an exemplary system infrastructure for a vehicle including a power converter, according to one or more embodiments.

FIG. 2 depicts an exemplary system infrastructure for a power converter, according to one or more embodiments.

FIG. 3 depicts an exemplary system infrastructure for a controller, according to one or more embodiments.

FIG. 4 depicts an exemplary dual side cooled printed circuit board with embedded power devices for an inverter, according to one or more embodiments.

FIG. 5 depicts an exemplary printed circuit board with embedded power devices and high voltage copper layers, according to one or more embodiments.

FIG. 6 depicts an exemplary system infrastructure for layers of a dual side cooled printed circuit board for an inverter and integrated Y-capacitor implementation, according to one or more embodiments.

FIG. 7 depicts an exemplary system infrastructure for a Y-capacitor implementation, according to one or more embodiments.

FIG. 8 depicts a detailed view of a lower portion of FIG. 6 and implementation of an integrated Y-capacitor, according to one or more embodiments.

### DETAILED DESCRIPTION OF EMBODIMENTS

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of ±10% in the stated value. In this disclosure, unless stated otherwise, any numeric value may include a possible variation of ±10% in the stated value.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section. For example, in the context of the disclosure, switching devices may be described as switches or devices, but may refer to any device for controlling the flow of power in an electrical circuit. For example, switches may be metal-oxide-semiconductor field-effect transistors (MOSFETs), bipolar junction transistors (BJTs), insulated-gate bipolar transistors (IGBTs), or relays, for example, or any combination thereof, but are not limited thereto.

Various embodiments of the present disclosure relate generally to systems and methods for inverters, and, more particularly, to systems and methods for common mode filters for inverters for electric vehicles. Inverters, such as those used to drive a motor in an electric vehicle, for example, are responsible for converting High Voltage Direct Current (HVDC) into Alternating Current (AC) to drive the motor. A three phase inverter may include a bridge with six power device switches (for example, power transistors such as IGBT or MOSFET) that are controlled by Pulse Width Modulation (PWM) signals generated by a controller. An inverter may include three half-H bridge switches to control the phase voltage, upper and lower gate drivers to control the switches, a PWM controller, and glue logic between the PWM controller and the gate drivers. The PWM controller may generate signals to define the intended states of the system. The gate drivers may send the signals from the PWM controller to the half-H bridge switches. The half-H bridge switches may drive the phase voltage. Six phase (or other phase) inverters, chargers, DC-DC converters, and/or multi-level inverters are not excluded from this concept and will follow similar principles. The present disclosure refers to an inverter as an example embodiment of a power converter. Power converters may include chargers, inverters, or DC-DC converters, for example.

Electric vehicles, energy storage systems, and backup generators, for example, convert electric power from one form to another. Additionally, an on-board charger for a vehicle, for example, may have a dual purpose. The on-board charger may be a bi-directional system that converts AC voltage to DC voltage in a charging mode (grid-to-battery) and DC voltage to AC voltage in a discharge or inverter mode (battery-to-grid). The charging mode may convert the grid AC into DC voltage to charge the vehicle high voltage (HV) battery, and the discharge or inverter mode may convert the HV battery DC voltage into AC voltage that may be supplied to a load of the grid line voltage, be supplied as a backup generator to power a house when the grid is down, or as an inverter to supply voltage to vehicle AC outlets, for example.

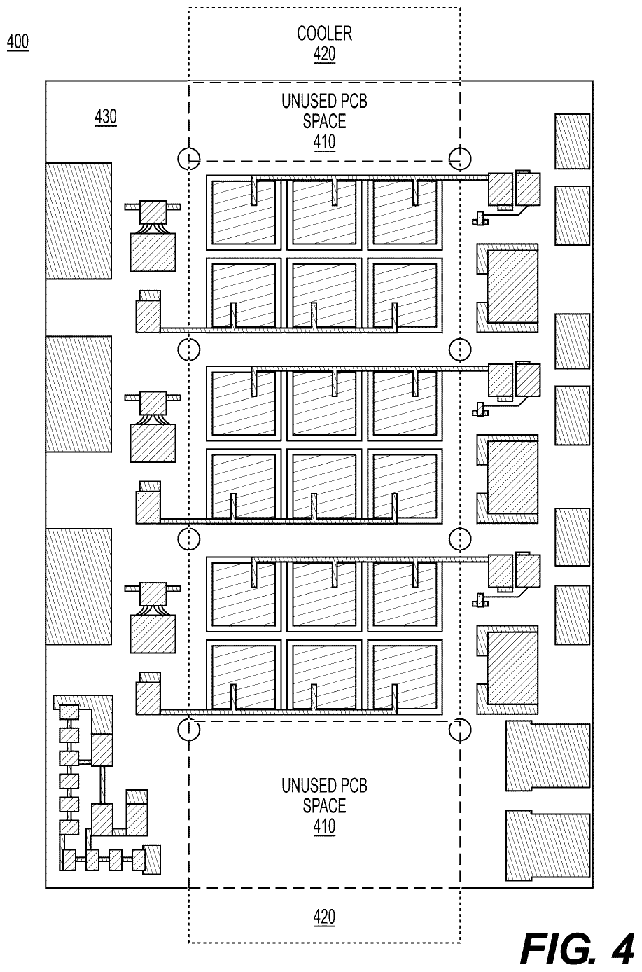

Isolation and cooling techniques on specialized heavy copper PCBs with embedded FETs may present one or more design challenges. To maintain cost competitiveness with embedded PCB designs, utilizing more “power PCB” space and refining the PCB (printed circuit board) size to obtain a higher number of PCBs per panel may lead to a more cost-efficient design. With a double side cooled embedded inverter design, considerable PCB space may be “lost” above and below the embedded FETs, as illustrated in FIG. 4. One or more embodiments may utilize the unused or previously “lost” space on the power PCB to create a “natural” common mode EMI filter (Y-Capacitor) component suitable to mitigate EMI in traction inverter applications.

One or more embodiments may take advantage of the pre-existing heavy copper planes (HVDC+ and HVDC−) around the “unused” space in the PCB and configure the plane shape and the plane area. One or more embodiments may provide HVDC (for example, high-voltage direct current) planes on the top and bottom layer of the PCB and cold plates attached to the top and bottom, which may provide an effective dielectric area between the two conductors. One or more embodiments may provide the cold plate being tied to the chassis ground, which may create a natural “Y-capacitance”acting as a common mode EMI filter to the system's benefit (for example, the inverter).

An effective capacitance between two plates and a dielectric area may be given by

$$C = κ {ε}_{0} \frac{A}{d}$$

where,
K—Effective dielectric constant of the material between the plates
ε₀—Permittivity of free space (8.85×10\hat{ }-12 F/m)
A—Area of the conductors (plates)
d—distance between the plates

One or more embodiments may provide components configured to change the values of the effective dielectric constant of the material between the plates, the area of the conductors, or the distance between the plates. One or more embodiments may provide one or more of the aforementioned parameters which may be refined or configured in embedded inverter designs to create an effective Y-capacitance. One or more embodiments may provide that some parameters may not offer high range of flexibility, such as the distance between the conductors and the effective dielectric constant. However, one or more embodiments may provide in practical embedded PCB designs and applications, that these parameters may naturally offer suitable magnitudes to create a small capacitance (for example, in nF) for common mode filtering.

One or more embodiments may provide that the area of the conductor may be a flexible parameter to effectively design and tune a Y-cap value since the part of the PCB (HV layer) is unused and the cold plate area in the region may not be required to extract heat. One or more embodiments may provide this natural benefit and may assist in effectively refining or configuring a Y-capacitance for use as a filter based on, for example, individual design requirements. One or more embodiments may provide at least one high voltage plate, at least one cold plate insulated from the at least one high voltage plate, and at least one printed circuit board layers insulating the at least one high voltage plate from the at least one cold plate. One or more embodiments may provide a thickness of the at least one printed circuit board configured to determine a dielectric constant between two conductors. One or more embodiments may include two cold plates acting as two different conductors, and two high voltage plates acting as two different conductors. One or more embodiments may provide a first cold plate insulated by a first dielectric from a first high voltage plate, and a second cold plate insulated by a second dielectric from a second high voltage plate. One or more embodiments may include one or more high voltage plates including a conductive plate.

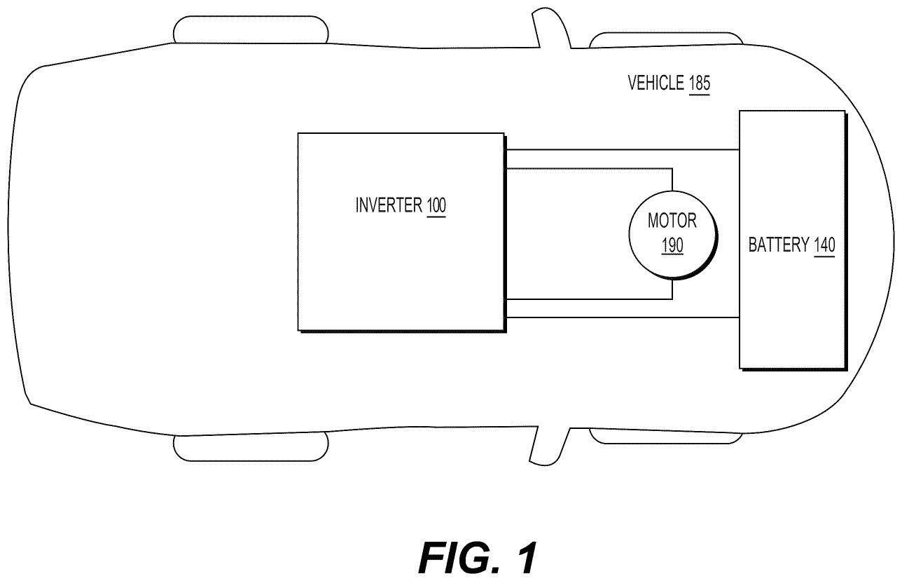

FIG. 1 depicts an exemplary system infrastructure for a vehicle including a power converter, according to one or more embodiments. The inverter 100 may be a combined inverter and converter. Alternatively, the inverter may be an inverter without a converter. In the context of this disclosure, a battery charger, the inverter, the converter, or any combination thereof may be referred to as inverter 100. Electric vehicle 185 may include inverter 100, motor 190, and battery 140. Inverter 100 may include components to receive electrical power from an external source and output electrical power to charge battery 140 of electric vehicle 185. Inverter 100 may convert DC power from battery 140 in electric vehicle 185 to AC power, to drive motor 190 of the electric vehicle 185, for example, but the embodiments are not limited thereto. For example, inverter 100 may include components to receive electrical power from an external source and output electrical power to charge battery 140 without motor 190 connected to inverter 100. Inverter 100 may convert DC power from battery 140 in electric vehicle 185 to AC power, to drive AC components other than motor 190 of the electric vehicle 185. Inverter 100 may be bidirectional, and may convert DC power to AC power, or convert AC power to DC power, such as during regenerative braking, for example. Inverter 100 may be a three-phase inverter, a single-phase inverter, or a multi-phase inverter.

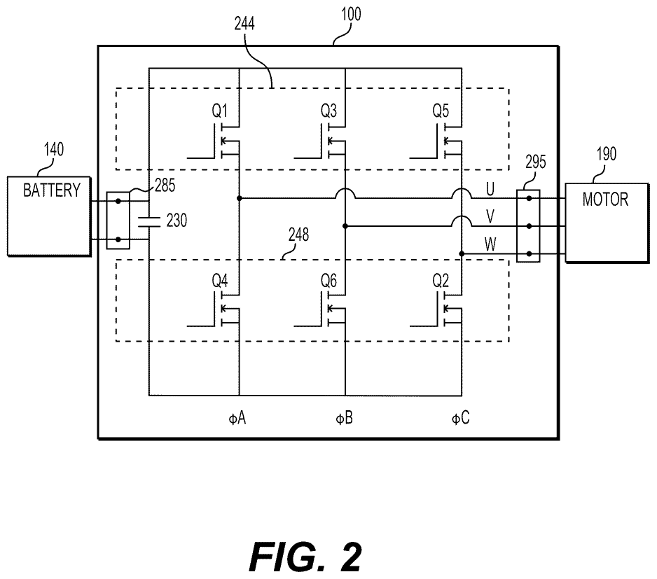

FIG. 2 depicts an exemplary system infrastructure for a power converter, according to one or more embodiments. Inverter 100 may be used to convert DC power from a battery in electric vehicle 185 to AC power, to drive motor 190 of electric vehicle 185, for example, but embodiments are not limited thereto. Additionally, inverter 100 may be bidirectional, and used to convert DC power to AC power, or to convert AC power to DC power.

Inverter 100 may be connected to battery 140 and motor 190. Inverter 100 may include upper phase switches 244 and lower phase switches 248. A first phase (φA) may include switches Q1 and Q4, a second phase (φB) may include switches Q3 and Q6, and a third phase (φC) may include switches Q5 and Q2. Upper phase switches 244 may include first phase switch Q1, second phase switch Q3, and third phase switch Q5. Lower phase switches 248 may include first phase switch Q4, second phase switch Q6, and third phase switch Q2. Switches Q1-Q6 may be metal-oxide-semiconductor field-effect transistors (MOSFET), for example, but embodiments are not limited thereto.

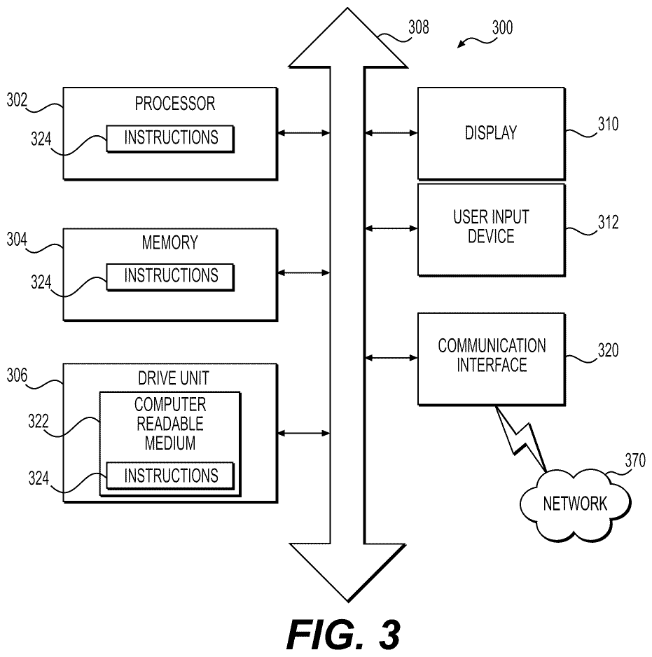

Upper phase switches 244 and lower phase switches 248 may be driven by a pulse width modulated (PWM) signal generated by controller 300 (e.g., see FIG. 3) to convert DC power delivered via the set of input terminals 285 at bulk capacitor 230 to three phase AC power at outputs U, V, and W (correlating with phases A, B, and C, respectively) via the set of output terminals 295 to motor 190. Additionally, although FIG. 2 depicts a three-phase inverter, the disclosure is not limited thereto, and may include single phase or multi-phase or multi-level inverters.

FIG. 3 depicts an exemplary system infrastructure for a controller, according to one or more embodiments. Controller 300 may include one or more controllers.

The controller 300 may include a set of instructions that can be executed to cause the controller 300 to perform any one or more of the methods or computer based functions disclosed herein. The controller 300 may operate as a standalone device or may be connected, e.g., using a network, to other computer systems or peripheral devices.

In a networked deployment, the controller 300 may operate in the capacity of a server or as a client in a server-client user network environment, or as a peer computer system in a peer-to-peer (or distributed) network environment. The controller 300 can also be implemented as or incorporated into various devices, such as a power converter, a personal computer (PC), a tablet PC, a set-top box (STB), a personal digital assistant (PDA), a mobile device, a palmtop computer, a laptop computer, a desktop computer, a communications device, a wireless telephone, a land-line telephone, a control system, a camera, a scanner, a facsimile machine, a printer, a pager, a personal trusted device, a web appliance, a network router, switch or bridge, or any other machine capable of executing a set of instructions (sequential or otherwise) that specify actions to be taken by that machine. In a particular implementation, the controller 300 can be implemented using electronic devices that provide voice, video, or data communication. Further, while the controller 300 is illustrated as a single system, the term “system” shall also be taken to include any collection of systems or sub-systems that individually or jointly execute a set, or multiple sets, of instructions to perform one or more computer functions.

As depicted in FIG. 3, the controller 300 may include a processor 302, e.g., a central processing unit (CPU), a graphics processing unit (GPU), or both. The processor 302 may be a component in a variety of systems. The processor 302 may be one or more general processors, digital signal processors, application specific integrated circuits, field programmable gate arrays, servers, networks, digital circuits, analog circuits, combinations thereof, or other now known or later developed devices for analyzing and processing data. The processor 302 may implement a software program, such as code generated manually (i.e., programmed).

The controller 300 may include a memory 304 that can communicate via a bus 308. The memory 304 may be a main memory, a static memory, or a dynamic memory. The memory 304 may include, but is not limited to computer readable storage media such as various types of volatile and non-volatile storage media, including but not limited to random access memory, read-only memory, programmable read-only memory, electrically programmable read-only memory, electrically erasable read-only memory, flash memory, magnetic tape or disk, optical media and the like. In one implementation, the memory 304 includes a cache or random-access memory for the processor 302. In alternative implementations, the memory 304 is separate from the processor 302, such as a cache memory of a processor, the system memory, or other memory. The memory 304 may be an external storage device or database for storing data. Examples include a hard drive, compact disc (“CD”), digital video disc (“DVD”), memory card, memory stick, floppy disc, universal serial bus (“USB”) memory device, or any other device operative to store data. The memory 304 is operable to store instructions executable by the processor 302. The functions, acts or tasks illustrated in the figures or described herein may be performed by the processor 302 executing the instructions stored in the memory 304. The functions, acts or tasks are independent of the particular type of instructions set, storage media, processor or processing strategy and may be performed by software, hardware, integrated circuits, firm-ware, micro-code and the like, operating alone or in combination. Likewise, processing strategies may include multiprocessing, multitasking, parallel processing and the like.

As depicted, the controller 300 may further include a display 310, such as a liquid crystal display (LCD), an organic light emitting diode (OLED), a flat panel display, a solid-state display, a cathode ray tube (CRT), a projector, a printer or other now known or later developed display device for outputting determined information. The display 310 may act as an interface for the user to see the functioning of the processor 302, or specifically as an interface with the software stored in the memory 304 or in the drive unit 306.

Additionally or alternatively, the controller 300 may include an input device 312 configured to allow a user to interact with any of the components of controller 300. The input device 312 may be a number pad, a keyboard, or a cursor control device, such as a mouse, or a joystick, touch screen display, remote control, or any other device operative to interact with the controller 300.

The controller 300 may also or alternatively include drive unit 306 implemented as a disk or optical drive. The drive unit 306 may include a computer-readable medium 322 in which one or more sets of instructions 324, e.g. software, can be embedded. Further, the instructions 324 may embody one or more of the methods or logic as described herein. The instructions 324 may reside completely or partially within the memory 304 and/or within the processor 302 during execution by the controller 300. The memory 304 and the processor 302 also may include computer-readable media as discussed above.

In some systems, a computer-readable medium 322 includes instructions 324 or receives and executes instructions 324 responsive to a propagated signal so that a device connected to a network 370 can communicate voice, video, audio, images, or any other data over the network 370. Further, the instructions 324 may be transmitted or received over the network 370 via a communication port or interface 320, and/or using a bus 308. The communication port or interface 320 may be a part of the processor 302 or may be a separate component. The communication port or interface 320 may be created in software or may be a physical connection in hardware. The communication port or interface 320 may be configured to connect with a network 370, external media, the display 310, or any other components in controller 300, or combinations thereof. The connection with the network 370 may be a physical connection, such as a wired Ethernet connection or may be established wirelessly as discussed below. Likewise, the additional connections with other components of the controller 300 may be physical connections or may be established wirelessly. The network 370 may alternatively be directly connected to a bus 308.

While the computer-readable medium 322 is depicted to be a single medium, the term “computer-readable medium” may include a single medium or multiple media, such as a centralized or distributed database, and/or associated caches and servers that store one or more sets of instructions. The term “computer-readable medium” may also include any medium that is capable of storing, encoding, or carrying a set of instructions for execution by a processor or that cause a computer system to perform any one or more of the methods or operations disclosed herein. The computer-readable medium 322 may be non-transitory, and may be tangible.

The computer-readable medium 322 can include a solid-state memory such as a memory card or other package that houses one or more non-volatile read-only memories. The computer-readable medium 322 can be a random-access memory or other volatile re-writable memory. Additionally or alternatively, the computer-readable medium 322 can include a magneto-optical or optical medium, such as a disk or tapes or other storage device to capture carrier wave signals such as a signal communicated over a transmission medium. A digital file attachment to an e-mail or other self-contained information archive or set of archives may be considered a distribution medium that is a tangible storage medium. Accordingly, the disclosure is considered to include any one or more of a computer-readable medium or a distribution medium and other equivalents and successor media, in which data or instructions may be stored.

In an alternative implementation, dedicated hardware implementations, such as application specific integrated circuits, programmable logic arrays and other hardware devices, can be constructed to implement one or more of the methods described herein. Applications that may include the apparatus and systems of various implementations can broadly include a variety of electronic and computer systems. One or more implementations described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

The controller 300 may be connected to a network 370. The network 370 may define one or more networks including wired or wireless networks. The wireless network may be a cellular telephone network, an 802.11, 802.16, 802.20, or WiMAX network. Further, such networks may include a public network, such as the Internet, a private network, such as an intranet, or combinations thereof, and may utilize a variety of networking protocols now available or later developed including, but not limited to TCP/IP based networking protocols. The network 370 may include wide area networks (WAN), such as the Internet, local area networks (LAN), campus area networks, metropolitan area networks, a direct connection such as through a Universal Serial Bus (USB) port, or any other networks that may allow for data communication. The network 370 may be configured to couple one computing device to another computing device to enable communication of data between the devices. The network 370 may generally be enabled to employ any form of machine-readable media for communicating information from one device to another. The network 370 may include communication methods by which information may travel between computing devices. The network 370 may be divided into sub-networks. The sub-networks may allow access to all of the other components connected thereto or the sub-networks may restrict access between the components. The network 370 may be regarded as a public or private network connection and may include, for example, a virtual private network or an encryption or other security mechanism employed over the public Internet, or the like.

In accordance with various implementations of the present disclosure, the methods described herein may be implemented by software programs executable by a computer system. Further, in an exemplary, non-limited implementation, implementations can include distributed processing, component or object distributed processing, and parallel processing. Alternatively, virtual computer system processing can be constructed to implement one or more of the methods or functionality as described herein.

Although the present specification describes components and functions that may be implemented in particular implementations with reference to particular standards and protocols, the disclosure is not limited to such standards and protocols. For example, standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same or similar functions as those disclosed herein are considered equivalents thereof.

It will be understood that the operations of methods discussed are performed in one embodiment by an appropriate processor (or processors) of a processing (i.e., computer) system executing instructions (computer-readable code) stored in storage. It will also be understood that the disclosure is not limited to any particular implementation or programming technique and that the disclosure may be implemented using any appropriate techniques for implementing the functionality described herein. The disclosure is not limited to any particular programming language or operating system.

FIG. 4 depicts an exemplary dual side cooled system infrastructure with embedded power devices for an embedded inverter, according to one or more embodiments. System 400 may include embedded inverter 430. Embedded inverter 430 may include cooler 420 and unused printed circuit board space 410. Cooler 420 may include double sided cooler.

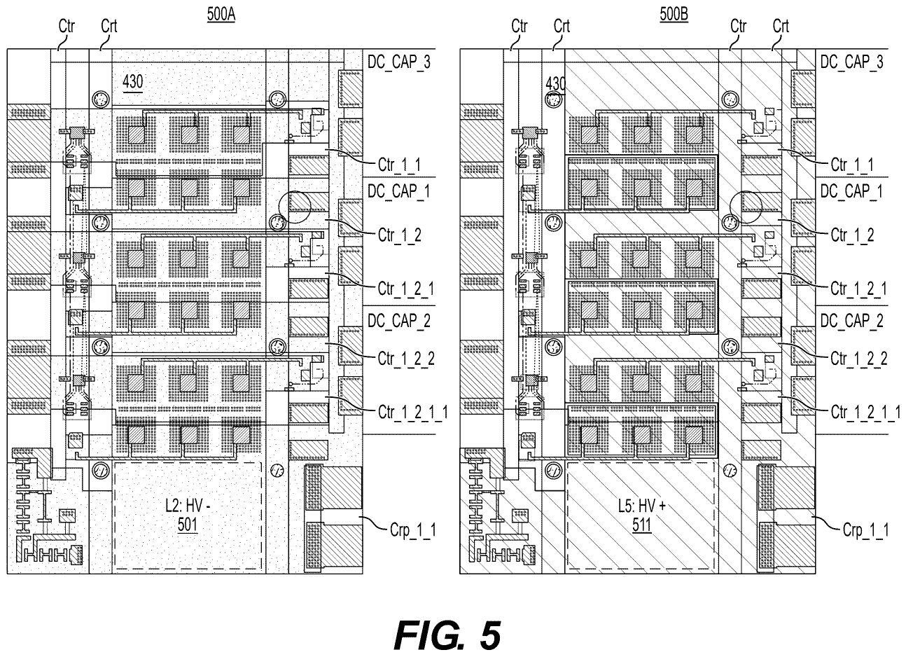

FIG. 5 depicts an exemplary printed circuit board with embedded power devices and high voltage copper layers, according to one or more embodiments. Embedded inverter 430 may include negative high-voltage layer 500A and positive high-voltage layer 500B. Negative high-voltage layer 500A may include unused space including negative high-voltage direct current 501. Positive high-voltage layer 500B may include unused space including positive high-voltage direct current 511.

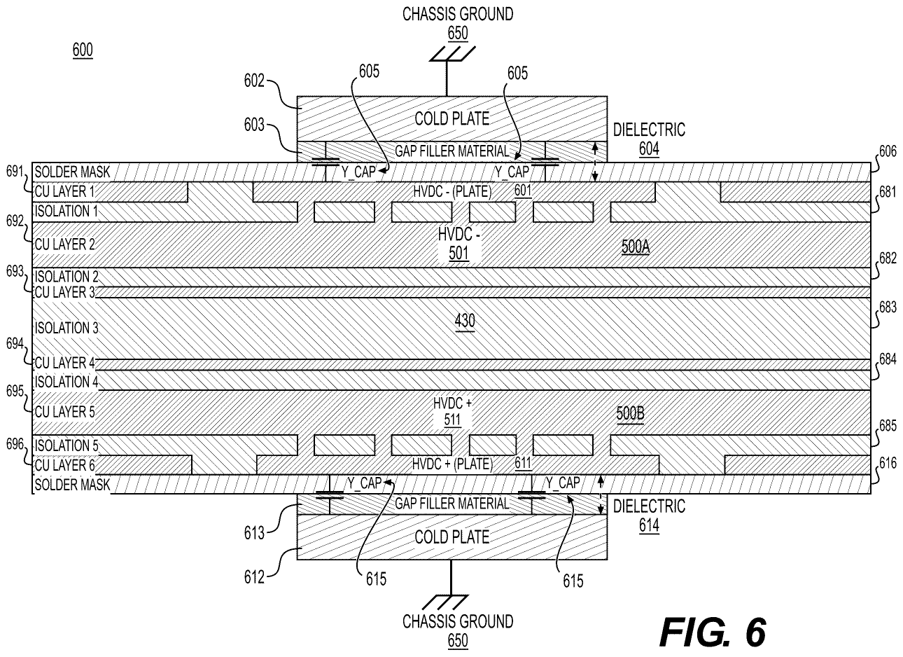

FIG. 6 depicts an exemplary system infrastructure of layers of a dual side cooled printed circuit board for an inverter and integrated Y-capacitor implementation, according to one or more embodiments. System 600 may include embedded inverter 430, including negative high-voltage layer 500A and positive high-voltage layer 500B. System 600 may include embedded inverter 430 seen from a layer view. Embedded inverter 430 may include negative high-voltage layer 500A, positive high-voltage layer 500B, negative high-voltage direct current 501, positive high-voltage direct current 511, negative high-voltage direct current plate 601, first cold plate 602, first gap filler material 603, first dielectric 604, first Y-capacitor 605, first solder mask 606, positive high-voltage direct current plate 611, second cold plate 612, second gap filler material 613, second dielectric 614, second Y-capacitor 615, second solder mask 616, first isolation layer 681, second isolation layer 682, third isolation layer 683, fourth isolation layer 684, fifth isolation layer 685, first copper layer 691, second copper layer 692, third copper layer 693, fourth copper layer 694, fifth copper layer 695, and sixth copper layer 696.

First Y-capacitor 605 may include negative high-voltage direct current plate 601, first dielectric 604, and first cold plate 602. First cold plate 602 may be connected to chassis ground 650. First dielectric 604 may include first solder mask 606 and first gap filler material 603. First Y-capacitor 605 may provide a capacitance in nF. First Y-capacitor 605 may include a system layer which may include first gap filler material 603 and first solder mask 606.

Second Y-capacitor 615 may include positive high-voltage direct current plate 611, second dielectric 614, and second cold plate 612. Second cold plate 612 may be connected to chassis ground 650. Second dielectric 614 may include second solder mask 616 and first gap filler material 603. Second Y-capacitor 615 may provide a capacitance in nF. Second Y-capacitor 615 may include a system layer which may include a second gap filler material 613 and second solder mask 616.

First Y-capacitor 605 and second Y-capacitor 615 may provide a capacitance in nF. First Y-capacitor 605 and second Y-capacitor 615 may provide a capacitance from approximately 100 pF to approximately 100 nF. First Y-capacitor 605 and second Y-capacitor 615 may provide the same or substantially the same capacitance. First Y-capacitor 605 and second Y-capacitor 615 may provide the same or substantially the same capacitance and may provide common mode filtering.

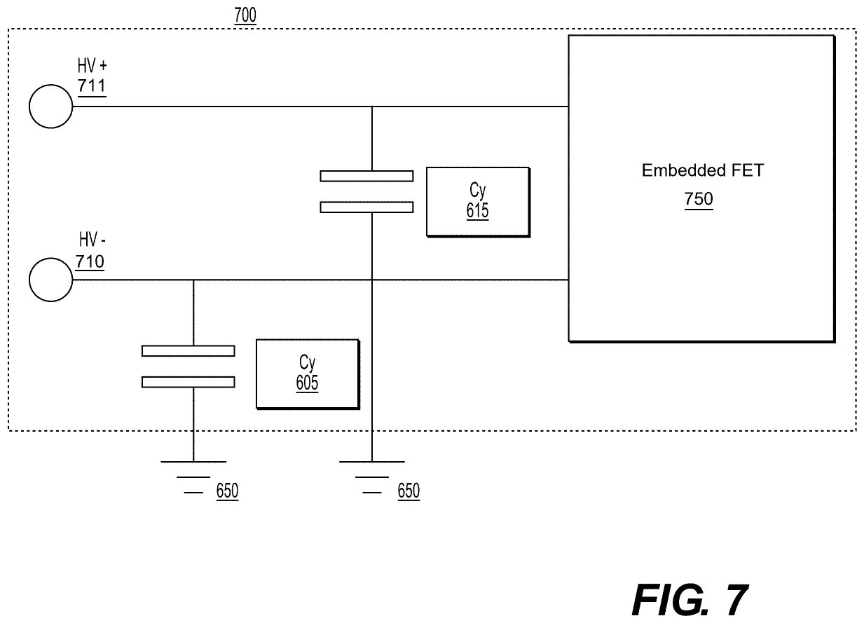

FIG. 7 depicts an exemplary system infrastructure for a Y-capacitor implementation, according to one or more embodiments. PCB 700 may include positive high-voltage source 711, negative high-voltage source 710, second Y-capacitor 615, and first Y-capacitor 605. PCB 700 may be electrically connected to embedded FET 750. Embedded FET 750 may include one or more embedded FETs. First Y-capacitor 605 may be connected to chassis ground 650, and second Y-capacitor 615 may be connected to chassis ground 650.

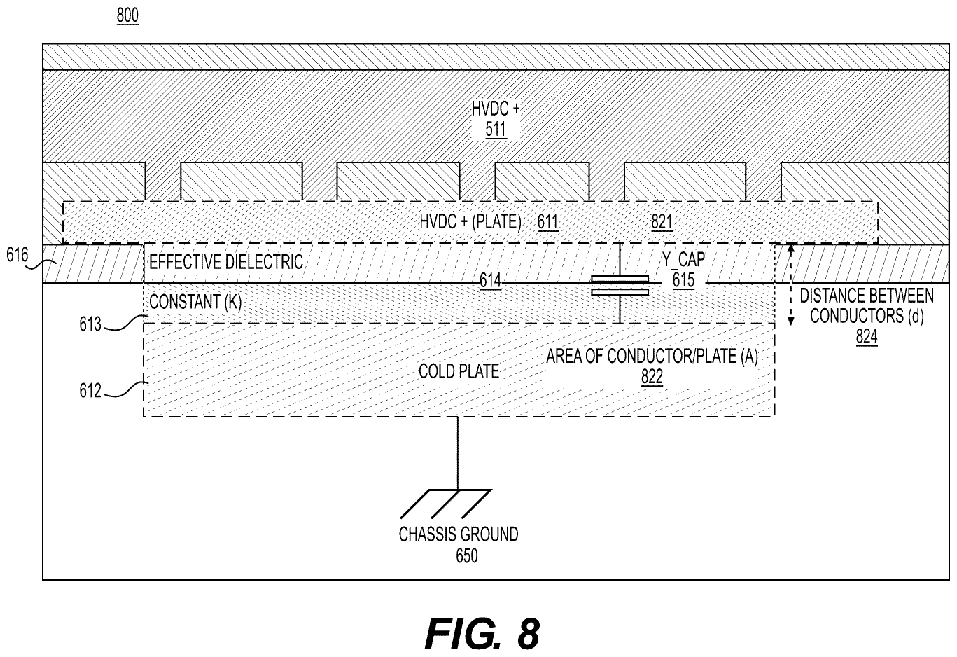

FIG. 8 depicts a detailed view of a lower portion of FIG. 6 and implementation of integrated Y-capacitor, according to one or more embodiments. System 800 may include second Y-capacitor 615 of system 600. Second Y-capacitor 615 may include positive high-voltage direct current 511, positive high-voltage direct current plate 611, second solder mask 616, second gap filler material 613, second cold plate 612, and may be connected to chassis ground 650. Second Y-capacitor 615 may be provided as a common mode EMI (electromagnetic interference) filter. Positive high-voltage direct current plate 611 may be a first conductor with an area-of-first-conductor 821. Second cold plate 612 may be a second conductor with an area-of-second-conductor 822. Second dielectric 614 may be a dielectric with an effective dielectric constant (K) and may include second solder mask 616 and may include second gap filler material 613. Second dielectric 614 may include one or more layers. Second dielectric 614 may be an insulator. Second gap filler material 613 may be a material configured to change the effective dielectric constant of the material between one or more conductors. Second solder mask 616 may be a material configured to change the effective dielectric constant of the material between one or more conductors. One or more layers of second dielectric 614 may be a material configured to change the effective dielectric constant of the material between one or more conductors (for example, positive high-voltage direct current plate 611 and second cold plate 612).

Second Y-capacitor 615 may provide that positive high-voltage direct current plate 611 is a distance equal to distance-between-conductors 824 from second cold plate 612. For example, distance-between-conductors 824 may include the distance between positive high-voltage direct current plate 611 and second cold plate 612, for example. Also, positive high-voltage direct current plate 611 may be insulated from second cold plate 612 by second dielectric 614. Positive high-voltage direct current plate 611 may be directly adjacent to second dielectric 614, and second dielectric 614 may be directly adjacent to second cold plate 612. Directly adjacent may include a first face of positive high-voltage direct current plate 611 against a first face of second dielectric 614 with no space or minimal space between the two faces, and may include a first face of second cold plate 612 against a second face of second dielectric 614 with no space or minimal space between the two faces.

With second cold plate 612 connected to chassis ground 650, second Y-capacitor 615 may create a small capacitance and may provide common mode filtering for an application. Second Y-capacitor 615 may be configured to produce a capacitance. Second Y-capacitor 615 may be configured to produce a capacitance that has been refined for use with embedded FET 750.

One or more embodiments may provide utilization of unused or previously “lost” space on a power printed circuit board and may provide a common mode EMI filter or Y-capacitor component. One or more embodiments may provide mitigation of electromagnetic interference in traction inverter applications. One or more embodiments may take advantage of pre-existing heavy copper planes (for example, positive HVDC plane, and negative HVDC plane) around space in a printed circuit board and configure or refine the plane shape or the plane area.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A system comprising:
an inverter configured to convert DC power from a battery to AC power to drive a motor, wherein the inverter includes:
a printed circuit board, wherein the printed circuit board includes:
at least one high voltage layer including a conductive plate; and
at least one cold plate electrically insulated from the at least one high voltage layer, wherein the at least one cold plate is electrically connected to ground.

2. The system of claim 1, wherein the inverter is double side cooled and the inverter is PCB based with embedded power devices or switches.

3. The system of claim 1, wherein the at least one high voltage layer includes a first high voltage plate and a second high voltage plate, wherein the first high voltage plate is a positive high voltage plate, and wherein the second high voltage plate is a negative high voltage plate.

4. The system of claim 1, further comprising at least one system layer, wherein a first face of the at least one system layer is directly adjacent to a face of at least one high voltage plate, and a second face of the at least one system layer is directly adjacent to a face of the at least one cold plate.

5. The system of claim 4, wherein the at least one system layer includes a solder mask.

6. The system of claim 4, wherein the at least one system layer includes a gap filler material.

7. The system of claim 4, wherein a thickness of the at least one system layer is configured to determine a distance between the at least one high voltage plate and the at least one cold plate.

8. The system of claim 4, wherein a thickness of the at least one system layer is configured to determine an effective dielectric constant between the at least one high voltage plate and the at least one cold plate.

9. The system of claim 4, wherein the at least one high voltage plate, the at least one cold plate, and the at least one system layer are configured to produce a capacitance.

10. The system of claim 4, wherein the at least one high voltage plate is a first conductor and the at least one cold plate is a second conductor, and wherein the at least one system layer has a thickness equal to a distance between the first conductor and the second conductor, wherein the distance between the first conductor and the second conductor is the distance in between the face of the at least one high voltage plate and the face of the at least one cold plate.

11. The system of claim 4, wherein the at least one high voltage plate, the at least one cold plate, and the at least one system layer are configured as a common mode electromagnetic interference filter.

12. The system of claim 4, wherein the at least one high voltage plate, the at least one cold plate, and the at least one system layer are configured as Y-capacitor.

13. The system of claim 1, further comprising:
one or more batteries,
wherein the system is provided as a bidirectional battery charger configured to:
receive an input AC power from a line voltage, convert the input AC power to an output DC power, and supply the output DC power to charge the one or more batteries in a grid-to-battery operation, and receive an input DC power from the one or more batteries, convert the input DC power to an output AC power, and supply the output AC power to a load of the line voltage in a battery-to-grid operation.

14. The system of claim 1, further comprising:
the battery; and
the motor,
wherein the system is provided as an electric vehicle.

15. A system comprising:
a printed circuit board, wherein the printed circuit board includes:
a first high voltage plate,
a first cold plate electrically connected to a ground,
a first system layer electrically insulating the first high voltage plate from the first cold plate,
a second high voltage plate,
a second cold plate electrically connected to the ground, and
a second system layer electrically insulating the first high voltage plate from the second cold plate.

16. The system of claim 15, wherein the first high voltage plate, the first cold plate, and the first system layer are configured to provide a first capacitance, and wherein the second high voltage plate, the second cold plate, and the second system layer are configured to provide a second capacitance.

17. The system of claim 15, wherein the first system layer comprises one or more first system layers, and the second system layer comprises one or more second system layers.

18. The system of claim 15, wherein the first high voltage plate, the first cold plate, and the first system layer, are provided as a Y-capacitor, and the second high voltage plate, the second cold plate, and the second system layer are provided as a second Y-capacitor.

19. A system comprising:
a printed circuit board, wherein the printed circuit board includes:
at least one high voltage plate; and
at least one cold plate electrically insulated from the at least one high voltage plate, wherein the at least one cold plate is electrically connected to ground.

20. The system of claim 19, further comprising at least one system layer, and wherein the at least one system layer, the at least one high voltage plate, and the at least one cold plate are provided as a Y-capacitor.
